(19) United States
(12) Patent Application Publication
(10) Pub. No.: US 2026/0150626 A1
(43) Pub. Date: May 28, 2026

(54) DEPOSITION APPARATUS, DEPOSITION METHOD OF DISPLAY DEVICE AND ELECTRONIC DEVICE INCLUDING DISPLAY DEVICE

(71) Applicant: Samsung Display Co., LTD., Yongin-si (KR)

(72) Inventors: Gi Hyun LEE, Yongin-si (KR); Seung In CHOI, Yongin-si (KR)

(21) Appl. No.: 19/265,256

(22) Filed: Jul. 10, 2025

(30) Foreign Application Priority Data
Nov. 22, 2024 (KR) 10-2024-0168141

(51) Int. Cl. H01L 21/66; C23C 14/04; C23C 14/28; C23C 14/54; G06T 7/00; H10K 71/10

(52) U.S. Cl. CPC H10P 74/23; C23C 14/042; C23C 14/28; C23C 14/54; G06T 7/001; G06T 2207/30148; G06T 2207/30164; H10K 71/10

(57) ABSTRACT

A deposition apparatus includes a deposition source including a plurality of deposition nozzles arranged in a direction to spray a deposition material, a rail disposed along a direction in which the deposition nozzles are arranged above the deposition source, and a moving module disposed on the rail and moving along the rail. The moving module includes a carrier on which a substrate is loaded, a deposition mask supported by the carrier and disposed under the substrate, a camera disposed on the carrier to capture an image of the deposition nozzles, a laser irradiator disposed on the carrier to radiate a laser toward the deposition nozzles, and a controller which analyzes the image captured by the camera and controls the laser irradiator.

This application claims priority to Korean Patent Application No. 10-2024-0168141, filed on Nov. 22, 2024, and all the benefits accruing therefrom under 35 U.S.C. 119, the content of which in its entirety is herein incorporated by reference.

### BACKGROUND

### 1. Field

The present disclosure relates to a deposition apparatus, a deposition method of a display device, and an electronic device including a display device.

### 2. Description of the Related Art

An organic light-emitting display device utilizes the phenomenon that electrons injected from a cathode and holes injected from an anode recombine in an organic thin film to form excitons, and light of a particular wavelength is generated as energy is released when the excitons relax from an excited state to the ground state.

In an organic light-emitting display device, vacuum deposition using a deposition apparatus may be used as a method for depositing an organic material or metal used as electrodes. The vacuum deposition may be carried out by placing a substrate on which an organic thin film is to be grown inside a vacuum chamber, bringing a deposition mask having a same pattern as the pattern of the thin film to be formed into contact with the substrate, and then evaporating or sublimating a deposition material such as an organic material using a deposition source to deposit the deposition material on the substrate.

### SUMMARY

In a process of depositing a deposition material, the deposition material may accumulate at deposition nozzles of a deposition source. As a result, the angle at which the deposition material is sprayed from the deposition nozzles may be changed.

Embodiments of the present disclosure provide a deposition apparatus that can ensure continuous operation of the deposition process by avoiding deposition material from accumulating at the deposition nozzles to thereby prevent the spraying angle of the deposition material from changing. Embodiments of the present disclosure also provide a deposition method of a display device (i.e., a deposition method for manufacturing a display device), and an electronic device including a display device.

However, embodiments of the present disclosure are not restricted to those set forth herein. The above and other embodiments of the present disclosure will become more apparent to one of ordinary skill in the art to which the present disclosure pertains by referencing the detailed description of the present disclosure given below.

According to an embodiment of the present disclosure, a deposition apparatus includes a deposition source including a plurality of deposition nozzles arranged in a direction to spray a deposition material, a rail disposed along a direction in which the deposition nozzles are arranged above the deposition source, and a moving module disposed on the rail, where the moving module moves along the rail. In such an embodiment, the moving module includes a carrier on which a substrate is loaded, a deposition mask supported by the carrier and disposed under the substrate, a camera disposed on the carrier, where the camera captures an image of the deposition nozzles, a laser irradiator disposed on the carrier, where the laser irradiator radiates a laser toward the deposition nozzles, and a controller which analyzes the image captured by the camera and controls the laser irradiator.

In an embodiment, the deposition apparatus may further include a chamber in which the deposition source, the rail and the moving module are accommodated, the moving module may further includes an acoustic sensor which detects sound inside the chamber, and the controller may analyze the sound detected by the acoustic sensor to control an operation of the rail.

In an embodiment, the substrate may be disposed under the carrier, and the moving module may further include a mask support extending downward from the carrier to support the deposition mask in a way such that the deposition mask is spaced apart from the carrier.

In an embodiment, an opening may be defined through the carrier in a thickness direction of the carrier, and the substrate and the deposition may mask at least partially overlap the opening.

In an embodiment, the camera and the laser irradiator may be disposed at an end of the carrier in a direction in which the carrier moves.

In an embodiment, the camera may be disposed further to a front than the laser irradiator in the direction in which the carrier moves.

In an embodiment, the controller may compare an image of the deposition nozzles captured by the camera with an image of the deposition nozzles acquired in advance, and control the laser irradiator to radiate laser to foreign substances at the deposition nozzles when it is determined that the foreign substances are accumulated at the deposition nozzles.

In an embodiment, the controller may compare sound inside the chamber detected by a sound sensor with sound inside the chamber acquired in advance, and, interrupt an operation of the rail when the sound inside the chamber detected by the sound sensor is different from the sound inside the chamber acquired in advance based on a comparison result.

In an embodiment, the controller may interrupt the operation of the rail when a decibel of the sound detected by the sound sensor is different from a decibel of the sound acquired in advance.

In an embodiment, the controller may interrupt the operation of the rail when a sound wave of the sound detected by the sound sensor is different from a sound wave of the sound acquired in advance.

According to an embodiment of the present disclosure, a deposition method of a display device includes loading a substrate on which a deposition material is to be deposited on a carrier of a moving module, moving the moving module along a rail disposed above deposition nozzles in a direction in which the deposition nozzles are arranged, capturing an image of the deposition nozzles by a camera of the moving module, and controlling, by a controller of the moving module, a laser irradiator of the moving module by analyzing the image captured by the camera.

In an embodiment, the controlling, by the controller, the laser irradiator by analyzing the image captured by the camera may include comparing, by the controller, the image of the deposition nozzle captured by the camera with an image of the deposition nozzle acquired in advance, and controlling, by the controller, the laser irradiator to irradiate a laser based on a comparison result.

In an embodiment, the controlling, by the controller, the laser irradiator to radiate the laser based on the comparison result may include controlling, by the controller, the laser irradiator to radiate the laser to foreign substances if there is a foreign substance in the image captured by the camera which was not in the image acquired in advance.

In an embodiment, the deposition method of a display device may further include detecting, by a sound sensor of the moving module, sound inside the chamber in which the deposition nozzles, the rail and the moving module are accommodated, and controlling, by the controller of the moving module, an operation of the rail by analyzing the sound detected by the sound sensor.

In an embodiment, the controlling, by the controller, the operation of the rail by analyzing the detected sound of the sound sensor may include comparing, by the controller, the sound inside the chamber detected by the sound sensor with sound inside the chamber acquired in advance, and interrupting, by the controller, the operation of the rail based on a comparison result.

In an embodiment, the interrupting, by the controller, the operation of the rail based on the comparison result may include interrupting, by the controller, the operation of the rail when the sound detected by the sound sensor is different from the sound acquired in advance.

In an embodiment, the interrupting, by the controller, the operation of the rail based on the comparison result may include interrupting, by the controller, the operation of the rail when a decibel of the sound detected by the sound sensor is different from a decibel of the sound acquired in advance.

In an embodiment, the interrupting, by the controller, the operation of the rail based on the comparison result may include interrupting, by the controller, the operation of the rail when a sound wave of the sound detected by the sound sensor is different from a sound wave of the sound acquired in advance.

According to an embodiment of the present disclosure, an electronic device includes a display device fabricated by a deposition apparatus, where the deposition apparatus includes a deposition source having a plurality of deposition nozzles arranged in a direction for spraying a deposition material, a rail disposed along a direction in which the deposition nozzles are arranged above the deposition source, and a moving module disposed on the rail and moving along the rail. In such an embodiment, the moving module includes a carrier on which a substrate is loaded, a deposition mask supported by the carrier and disposed under the substrate, a camera disposed on the carrier, where the camera captures an image of the deposition nozzles, a laser irradiator disposed on the carrier, where the laser irradiator radiates a laser toward the deposition nozzles, and a controller which analyzes the image captured by the camera and controls the laser irradiator.

In an embodiment, The deposition apparatus may further include a chamber in which the deposition source, the rail and the moving module are accommodated, and the moving module may further include an acoustic sensor which detects sound inside the chamber, and the controller may analyze the sound detected by the acoustic sensor to control an operation of the rail.

According to an embodiment of the present disclosure, it is possible to ensure continuous operation of the deposition process by avoiding deposition material from accumulating at deposition nozzles of a deposition apparatus such that the spraying angle of a deposition material may be effectively prevented from changing.

The effects according to the embodiments of the present disclosure are not limited to those mentioned above and more various effects are included in the following description of the present disclosure.

### BRIEF DESCRIPTION OF THE DRAWINGS

The above and other features of embodiments of the present disclosure will become more apparent by describing in detail embodiments thereof with reference to the attached drawings, in which:

FIG. 1 is a side view showing a deposition apparatus according to an embodiment of the present disclosure;

FIG. 2 is a front view of the movement module of FIG. 1;

FIG. 3 is a side view of the movement module of FIG. 1;

FIG. 4 is a front view of the movement module of FIG. 3;

FIG. 5 is a plan view of the movement module of FIG. 3;

FIG. 6 is a block diagram showing the rail, a camera, a laser irradiator, an acoustic sensor and a controller of FIG. 3;

FIG. 7 is a view showing that a moving module having a substrate mounted thereon moves along a rail in a method for fabricating a display device according to an embodiment of the present disclosure;

FIG. 8 is a view showing the laser irradiator of FIG. 7 removing foreign substances from deposition nozzles;

FIG. 9 is a view showing the laser irradiator of FIG. 7 moving along the rail after removing foreign substances from deposition nozzles;

FIG. 10 is a plan view of a display device fabricated by a deposition apparatus according to an embodiment of the present disclosure;

FIG. 11 is a cross-sectional view taken along line A-A′ of FIG. 10;

FIG. 12 is a cross-sectional view showing the display panel of FIG. 11;

FIG. 13 is a plan view of an electronic device fabricated by a deposition apparatus according to an embodiment of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Features of various example embodiments of the present disclosure may be combined partially or totally. As will be clearly appreciated by those skilled in the art, technically various interactions and operations are possible. Various example embodiments can be practiced individually or in combination.

Hereinafter, embodiments of the present disclosure will be described in detail with reference to the accompanying drawings.

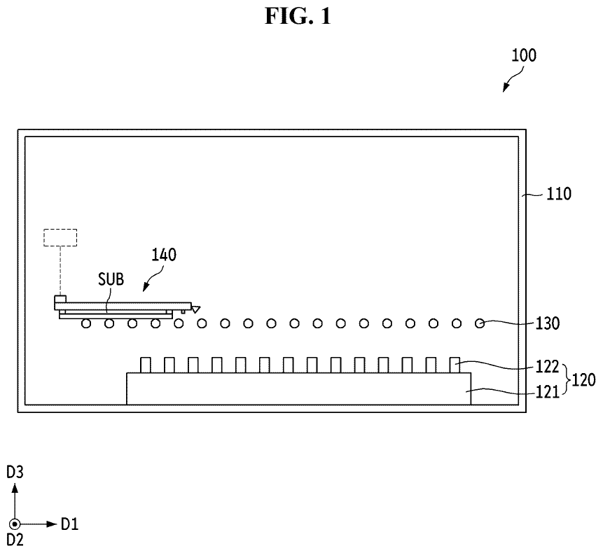

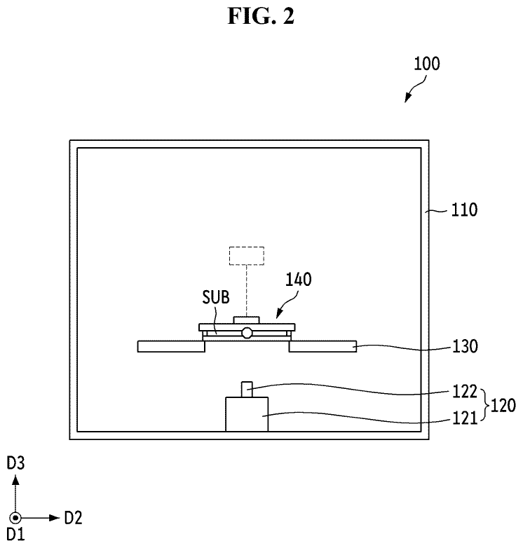

FIG. 1 is a side view showing a deposition apparatus according to an embodiment of the present disclosure. FIG. 2 is a front view of the deposition apparatus of FIG. 1.

Referring to FIGS. 1 and 2, a deposition apparatus 100 according to an embodiment of the present disclosure may include a chamber 110, a deposition source 120, a rail 130, and a moving module 140.

The chamber 110 may provide a space for performing a deposition process. The inside of the chamber 110 may be maintained in a vacuum state while performing the deposition process. The inside of the chamber 110 in the vacuum state may mean maintaining the pressure inside the chamber 110 at a low pressure. The chamber 110 may include an inlet/outlet (not shown) for loading/unloading a substrate SUB. In addition, the chamber 110 may include a vacuum pump (not shown) for controlling the pressure inside the chamber 110 and discharging a deposition material that is not deposited on the substrate SUB, and an exhaust port (not shown) connected to the vacuum pump.

The substrate SUB on which the organic material or metal used as the electrode is deposited may be provided as an insulating substrate, a semiconductor substrate, a display device substrate, etc., but the present disclosure is not limited thereto. According to an embodiment, the substrate SUB used in an organic light-emitting display device is described as an example. A predetermined structure may be formed on the substrate SUB via a deposition process. Depending on the fabrication process of the organic light-emitting display device, the structure formed on the substrate SUB via the deposition process can be formed in various ways. In an embodiment, for example, in a process of forming a hole injection layer, a pixel-defining layer and an anode electrode may be formed on the substrate SUB. In addition, in a process of forming an organic light-emitting layer, not only a pixel-defining layer and an anode electrode, but also a hole injection layer and a hole transport layer may be formed on the substrate SUB.

The deposition source 120 may provide a deposition material to be deposited on the substrate SUB. The deposition source 120 may be disposed on the lower side in the chamber 110. The deposition source 120 may include a deposition source body 121 and a plurality of deposition nozzles 122.

The deposition source body 121 may support the plurality of deposition nozzles 122. The deposition source body 121 may be provided as a block having a predetermined thickness and may extend in a first direction D1 at the bottom in (or on an inner bottom surface of) the chamber 110. A space for accommodating a deposition material may be provided or formed in the deposition source body 121.

The deposition nozzles 122 may provide the deposition material to the substrate SUB by spraying the deposition material. The deposition nozzles 122 may be disposed on the upper surface of the deposition source body 121 and supported by the deposition source body 121. The deposition nozzles 122 may be spaced apart from one another in the first direction D1 on the upper surface of the deposition source body 121.

The rail 130 may be disposed above the deposition source 120. The rail 130 may be disposed along the direction in which the deposition nozzles 122 are arranged above the deposition source 120. In some embodiments, the rail 130 may be disposed along the first direction D1 above the deposition source 120. The rail 130 may include a plurality of rollers. The rollers may be spaced apart from one another along the first direction D1 above the deposition source 120. The rail 130 may be disposed at both opposing sides of the deposition source 120 above the deposition source 120. In some embodiments, the rail 130 may be disposed on the both opposing sides of the deposition source 120 to form a space for the deposition material to flow. The rail 130 may be disposed under the moving module 140, and the moving module 140 may be moved in the first direction D1 by the operation of the rail 130.

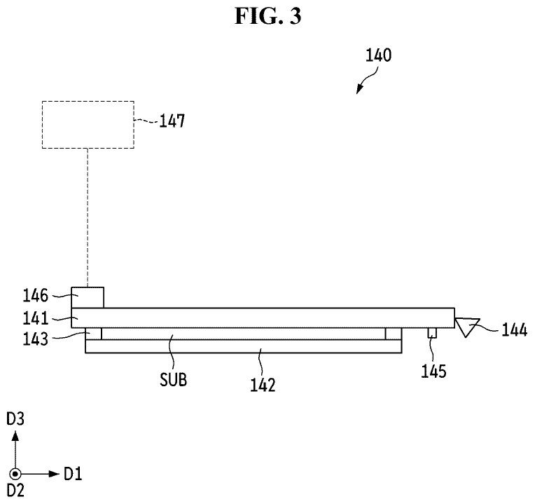

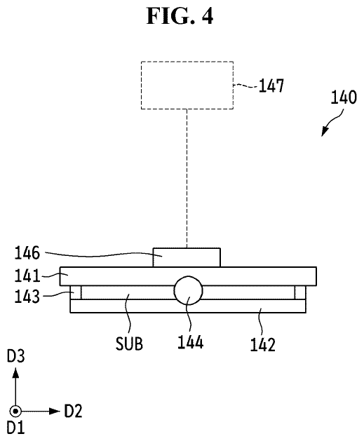

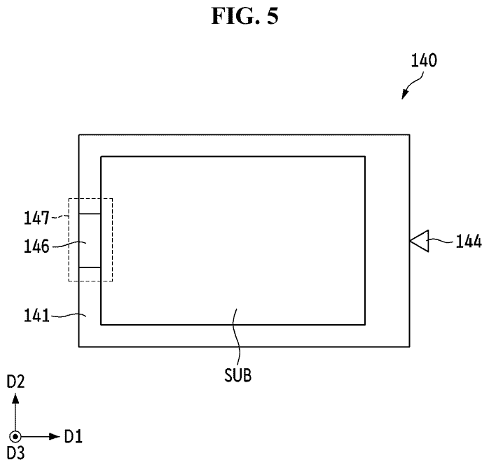

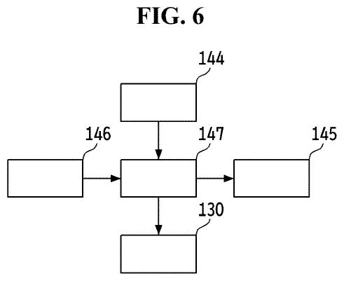

FIG. 3 is a side view of the moving module of FIG. 1. FIG. 4 is a front view of the moving module of FIG. 3. FIG. 5 is a plan view of the moving module of FIG. 3. FIG. 6 is a block diagram showing the rail, a camera, a laser irradiator, an acoustic sensor and a controller of FIG. 3.

Referring to FIGS. 3 to 6, in an embodiment, the moving module 140 may be disposed on the rail 130 and may be moved along the rail 130. In some embodiments, the moving module 140 may be moved in the first direction D1 by the operation of the rail 130. The moving module 140 may include a carrier 141, a deposition mask 142, a mask support 143, a camera 144, a laser irradiator 145, an acoustic sensor 146, and a controller 147.

The carrier 141 may hold the substrate SUB. The shape of the carrier 141 when viewed from the top (or in a plan view) may be a rectangular shape, and may have a predetermined thickness. An opening may be defined or formed in the center of the carrier 141 through the carrier 141 or to penetrate the carrier 141 in a thickness direction of the carrier 141 (or a third direction D3). The opening may overlap the substrate SUB and the deposition mask 142. The substrate SUB may be disposed under the carrier 141 and held by the carrier 141.

The deposition mask 142 may be supported by the carrier 141 and may be disposed under the substrate SUB. The deposition mask 142 may be connected to the carrier 141 by the mask support 143. The deposition mask 142 may define a region of the substrate SUB where a deposition material sprayed from the deposition source 120 is deposited. The deposition mask 142 may include a mask portion and a transmissive portion. The mask portion may cover a region of the substrate SUB to prevent the deposition material sprayed from the deposition source 120 from being deposited in that region. The transmissive portion exposes a region of the substrate SUB and may be an open area defined or formed in the mask portion. The deposition material may be deposited on the region of the substrate SUB exposed by the transmissive portion.

The mask support 143 may extend downward from the carrier 141 and may be connected to the deposition mask 142. In some embodiments, the mask support 143 may connect the carrier 141 with the deposition mask 142 so that the deposition mask 142 is supported by the carrier 141. Since the mask support 143 extends downward from the carrier 141, the mask support 143 may support the deposition mask 142 in a way such that the deposition mask 142 is spaced apart from the carrier 141.

The camera 144 may be disposed at the carrier 141 to capture images of the deposition nozzles 122. The camera 144 may be disposed at the end of the carrier 141 in the direction in which the carrier 141 moves. In an embodiment, for example, the camera 144 may be disposed at the right end of the carrier 141 in the first direction D1 in FIG. 3. The camera 144 may capture images of the deposition nozzles 122 disposed in front of the direction in which the moving module 140 moves when the moving module 140 is moved. The camera 144 may transmit captured images of the deposition nozzles 122 to the controller 147.

The laser irradiator 145 may be disposed on the carrier 141 to radiate laser toward the deposition nozzles 122. The laser irradiator 145 may be disposed at the end of the carrier 141 in the direction in which the carrier 141 moves. In an embodiment, for example, the laser irradiator 145 may be disposed at the right end of the carrier 141 in the first direction D1. The laser irradiator 145 may be disposed behind the camera 144 in the direction in which the moving module 140 moves. In some embodiments, the camera 144 may be disposed further to the front in the direction in which the moving module 140 moves than the laser irradiator 145.

The acoustic sensor 146 may be disposed on the carrier 141 to detect sound in the chamber 110. The acoustic sensor 146 may transmit the detected sound in the chamber 110 to the controller 147.

The controller 147 may analyze the captured images of the camera 144 to control the laser irradiator 145. In some embodiments, the controller 147 may compare the images of the deposition nozzles 122 captured by the camera 144 with the images of the deposition nozzles 122 acquired in advance (e.g., reference images of the deposition nozzles 122_, and may control the laser irradiator 145 based on a comparison result, i.e., a result obtained by comparing the images of the deposition nozzles 122 captured by the camera 144 with the images of the deposition nozzles 122 acquired in advance. In an embodiment, for example, when there are foreign substances or the like in the image of the deposition nozzles 122 captured by the camera 144 which were not in the image of the deposition nozzles 122 acquired in advance, the controller 147 may determine that there are foreign substances at the deposition nozzles 122. When it is determined that there are foreign substances at the deposition nozzles 122, the controller 147 may control the laser irradiator 145 to radiate the laser onto the foreign substances. The foreign substances accumulated at the deposition nozzles 122 may be removed by the laser radiated from the laser irradiator 145.

In an embodiment, the controller 147 may analyze the sound detected by the acoustic sensor 146 to control the operation of the rail 130. In some embodiments, the controller 147 may compare the sound in the chamber 110 detected by the acoustic sensor 146 with the sound in the chamber 110 acquired in advance (e.g., reference sound), and may control the operation of the rail 130 based on a comparison result. In an embodiment, for example, when the sound inside the chamber 110 detected by the sound sensor 146 is different from the sound inside the chamber 110 acquired in advance, the controller 147 may determine that there is an abnormality in the deposition apparatus 100. When the normal sound inside the chamber 110, i.e., the sound inside the chamber 110 acquired in advance while the deposition apparatus 100 is operating normally, is different from the current sound inside the chamber 110 detected by the sound sensor 146, the controller 147 may determine that an abnormality has occurred in the deposition apparatus 100. When it is determined that there is an abnormality in the deposition apparatus 100, the controller 147 may interrupt the operation of the rail 130 to stop the movement of the moving module 140.

When the decibel of the sound inside the chamber 110 detected by the sound sensor 146 is different from the decibel of the sound inside the chamber 110 acquired in advance, the controller 147 may determine that there is an abnormality in the deposition apparatus 100 and interrupt the operation of the rail 130. When the sound wave of the sound inside the chamber 110 detected by the sound sensor 146 is different from the sound wave of the sound inside the chamber 110 acquired in advance, the controller 147 may determine that there is an abnormality in the deposition apparatus 100 and interrupt the operation of the rail 130.

Hereinafter, a deposition method of a display device according to an embodiment of the present disclosure will be described with reference to the accompanying drawings.

A deposition method of a display device according to an embodiment of the present disclosure may include: loading a substrate SUB, on which a deposition material is to be deposited, on a carrier 141; moving a moving module 140 along a rail 130 disposed above deposition nozzles 122 in a direction in which the deposition nozzles 122 are arranged; capturing an image of the deposition nozzles 122 by a camera 144; and controlling a laser irradiator 145 by analyzing the image captured by the camera 144 by the controller 147.

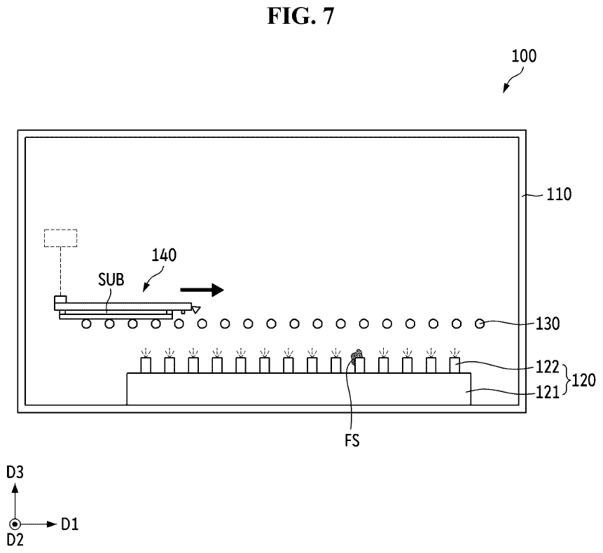

FIG. 7 is a view showing that a moving module having a substrate mounted thereon moves along a rail in a method for fabricating a display device according to an embodiment of the present disclosure.

Referring to FIG. 7, in an embodiment of a deposition method of a display device, the loading the substrate SUB on the carrier 141 may include loading the substrate SUB under the carrier 141. In some embodiments, the substrate SUB may be mounted on the carrier 141 between the carrier 141 and the deposition mask 142.

In an embodiment of a deposition method of a display device, the moving the moving module 140 along the rail 130 in the direction in which the deposition nozzles 122 are arranged may include moving the carrier 141 having the substrate SUB loaded thereon in the first direction D1 on the rail 130 according to the operation of the rail 130. In some embodiments, the carrier 141 may pass over the deposition nozzles 122 along the rail 130. While the carrier 141 passes over the deposition nozzles 122, deposition materials sprayed from the deposition nozzles 122 may pass through the deposition mask 142 and may be deposited on the substrate SUB.

In the capturing the image of the deposition nozzles 122 by the camera 144, the camera 144 disposed at the end of the carrier 141 in the direction in which the carrier 141 moves may capture the image of the deposition nozzles 122 disposed on the front side in the direction in which the moving module 140 moves while the moving module 140 is moving. The camera 144 may transmit captured images of the deposition nozzles 122 to the controller 147.

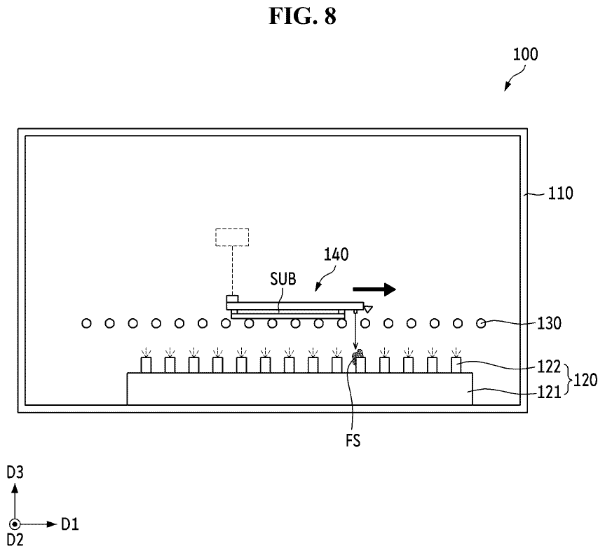

FIG. 8 is a view showing the laser irradiator of FIG. 7 removing foreign substances from deposition nozzles.

Referring to FIG. 8, the controlling the laser irradiator 145 by analyzing the image captured by the camera 144 by the controller 147 may include: comparing, by the controller 147, the images of the deposition nozzles 122 captured by the camera 144 with the images of the deposition nozzles acquired in advance; and controlling, by the controller 147, the laser irradiator 145 based on a comparison result to radiate laser. In an embodiment, for example, the controller 147 may compare the images of the deposition nozzles 122 captured by the camera 144 with the images of the deposition nozzles 122 acquired in advance, and may control the laser irradiator 145 based on the comparison result. When it is determined that there are foreign substances or the like in the image of the deposition nozzles 122 captured by the camera 144 which were not in the image of the deposition nozzles 122 acquired in advance, the controller 147 may determine that there are foreign substances at the deposition nozzles 122. When it is determined that there are foreign substances at the deposition nozzles 122, the controller 147 may control the laser irradiator 145 to radiate the laser onto the foreign substances. The foreign substances accumulated at the deposition nozzles 122 may be removed by the laser radiated from the laser irradiator 145.

A deposition method of a display device according to an embodiment of the present disclosure may further include: detecting the sound inside the chamber 110 by the acoustic sensor 146; and controlling the operation of the rail 130 by analyzing the sound detected by the acoustic sensor 146 by the controller 147.

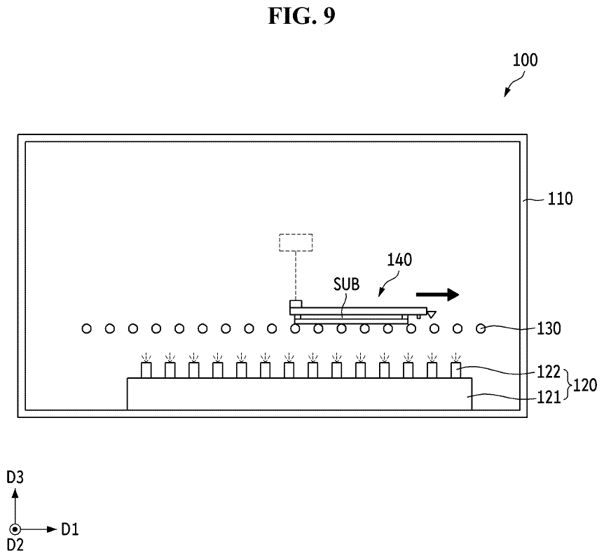

FIG. 9 is a view showing the laser irradiator of FIG. 7 moving along the rail after removing foreign substances from deposition nozzles.

Referring to FIG. 9, after the foreign substances accumulated at the deposition nozzle 122 are removed by the laser irradiator 145, the moving module 140 may move along the rail 130, and a deposition material may be deposited on the substrate SUB. The detecting the sound inside the chamber 110 by the acoustic sensor 146 may include detecting the sound inside the chamber 110 by the acoustic sensor 146 during a process of continuously depositing a deposition material on the substrate SUB. The acoustic sensor 146 may transmit the detected sound in the chamber 110 to the controller 147.

The controlling the operation of the rail 130 by analyzing the sound detected by the acoustic sensor 146 by the controller 147 may include: comparing, by the controller 147, the sound inside the chamber 110 detected by the sound sensor 146 with the sound inside the chamber 110 acquired in advance; and interrupting, by the controller 147, the operation of the rail 130 based on the comparison result. In an embodiment, for example, the controller 147 may compare the sound in the chamber 110 detected by the acoustic sensor 146 with the sound in the chamber 110 acquired in advance, and may control the operation of the rail 130 based on the comparison result. When the sound inside the chamber 110 detected by the sound sensor 146 is different from the sound inside the chamber 110 acquired in advance, the controller 147 may determine that there is an abnormality in the deposition apparatus 100. When the normal sound inside the chamber 110, i.e., the sound inside the chamber 110 acquired in advance while the deposition apparatus 100 is operating normally, is different from the current sound inside the chamber 110 detected by the sound sensor 146, the controller 147 may determine that an abnormality has occurred in the deposition apparatus 100. When it is determined that there is an abnormality in the deposition apparatus 100, the controller 147 may interrupt the operation of the rail 130 to stop the movement of the moving module 140.

When the decibel of the sound inside the chamber 110 detected by the sound sensor 146 is different from the decibel of the sound inside the chamber 110 acquired in advance, the controller 147 may determine that there is an abnormality in the deposition apparatus 100 and interrupt the operation of the rail 130. When the sound wave of the sound inside the chamber 110 detected by the sound sensor 146 is different from the sound wave of the sound inside the chamber 110 acquired in advance, the controller 147 may determine that there is an abnormality in the deposition apparatus 100 and interrupt the operation of the rail 130.

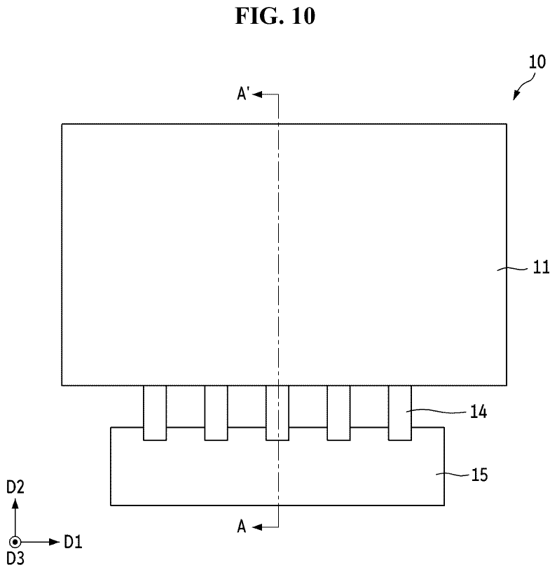

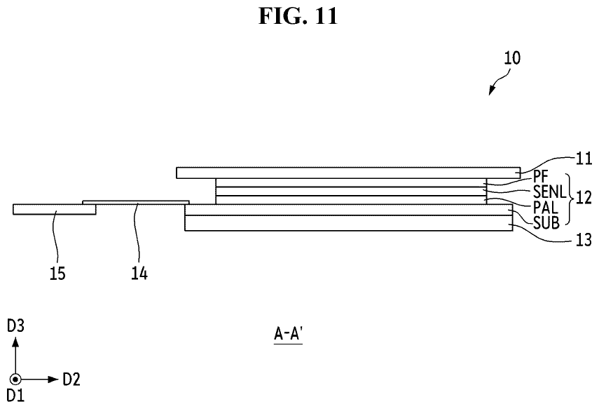

FIG. 10 is a plan view of a display device fabricated by a deposition apparatus according to an embodiment of the present disclosure. FIG. 11 is a cross-sectional view taken along line A-A′ of FIG. 10.

The display device 10 fabricated by the deposition apparatus 100 according to an embodiment of the present disclosure may be a light-emitting display device such as an organic light-emitting display device using organic light-emitting diodes, a quantum-dot light-emitting display device including quantum-dot light-emitting layer, an inorganic light-emitting display device including an inorganic semiconductor, and a micro light-emitting display device using micro light-emitting diodes (LED). Hereinafter, for convenience of description, embodiments where the display device 10 is an organic light-emitting display device will be mainly described as an example. It is, however, to be understood that the present disclosure is not limited thereto.

In an embodiment, the display device 10 may have a quadrangular shape when viewed from the top, such as a rectangle. In an embodiment, for example, the display device 10 may have a rectangular shape having longer sides in the first direction D1 and shorter sides in a second direction D2 crossing the first direction D1 when viewed from the top. The corners where the longer sides in the first direction D1 meet the shorter sides in the second direction D2 may be rounded with a predetermined curvature or may be a right angle. The shape of the display device 10 when viewed from the top is not limited to a rectangular shape, but may be formed in a different polygonal shape, a circular shape, or an elliptical shape.

Referring to FIGS. 10 and 11, the display device 10 fabricated by the deposition apparatus 100 according to an embodiment of the present disclosure may include a cover window 11, a display panel 12, a panel bottom member 13, a connecting member 14, and a driver circuit board 15.

The cover window 11 may include a material with high light transmittance. The cover window 11 may include a polymer resin such as polyimide or glass. The cover window 11 may be attached onto a polarizing film PF of the display panel 12 by an adhesive member such as an optically clear adhesive (OCA) film.

The display panel 12 may be disposed under the cover window 11. The display panel 12 may have a rectangular shape having longer sides in the first direction D1 and shorter sides in the second direction D2 when viewed from the top. In the display panel 12, the corners where the longer sides in the first direction D1 meet the shorter sides in the second direction D2 may be formed at a right angle or may be rounded with a predetermined curvature. The display panel 12 may have a quadrangular shape other than a rectangle, a polygonal shape other than a quadrangular shape, a circular shape, an oval shape, or an irregular shape when viewed from the top.

The display panel 12 may include a display area where a plurality of emission areas that emits light is arranged, and a non-display area disposed around the display area. The non-display area may surround the display area. A plurality of display pads may be disposed in the non-display area at one edge of the display panel 12.

The display panel 12 may include a substrate SUB, a display unit PAL, a sensor unit SENL and a polarizing film PF.

The substrate SUB may include or be made of an insulating material such as glass, quartz and a polymer resin. The substrate SUB may be a rigid substrate or a flexible substrate that can be bent, folded, rolled, and so on.

The display unit PAL may be disposed on the substrate SUB. The display unit PAL may be a layer including a plurality of emission areas that emit light. The display unit PAL may include a buffer film, a thin-film transistor layer on which thin-film transistors are disposed, a light-emitting element layer that emits light, and an encapsulating layer for encapsulating the light-emitting element layer.

The sensor unit SENL may be disposed on the display unit PAL. The sensor unit SENL may include sensor electrodes and may sense whether there is a user's touch.

The polarizing film PF may be disposed on the sensor unit SENL. The polarizing film PF may effectively prevent the deterioration of image visibility of the display panel 200 due to reflection of external light. The polarizing film may include a linear polarizer and a retardation film such as a λ/4 (quarter-wave) plate. The phase retardation film may be disposed on the sensor unit SENL, and the linear polarizer may be disposed on the phase retardation film. The cover window 11 may be disposed on the polarizing film PF.

The panel bottom member 13 may be disposed under the substrate SUB. The panel bottom member 13 may be attached to the lower surface of the substrate SUB by an adhesive member. The adhesive member may be a pressure-sensitive adhesive (PSA). The panel bottom member 13 may include at least one selected from: a light-absorbing member for absorbing light incident from outside, a buffer member for absorbing external impact, and a heat dissipating member for efficiently discharging heat from the display panel 12.

The light-absorbing member may be disposed under the substrate SUB. The light-absorbing member blocks the transmission of light to effectively prevent the elements disposed thereunder, such as the driver circuit board 15, from being seen from above the display panel 12. The light-absorbing member may include a light-absorbing material such as a black pigment and a black dye.

The buffer member may be disposed under the light-absorbing member. The buffer member absorbs an external impact to prevent the display panel 12 from being damaged. The buffer member may be made up of a single layer or multiple layers. In an embodiment, for example, the buffer member may include or be formed of a polymer resin such as polyurethane, polycarbonate, polypropylene and polyethylene, or may include or be formed of a material having elasticity such as a rubber and a sponge obtained by foaming a urethane-based material or an acrylic-based material.

The heat dissipating member may be disposed under the buffer member. The heat dissipation member may include a first heat dissipation layer including graphite or carbon nanotubes, and a second heat dissipation layer formed of a thin metal film such as copper, nickel, ferrite and silver, which can block electromagnetic waves and have high thermal conductivity.

The connecting member 14 may be connected to a plurality of display pads of the display panel 12 through a conductive adhesive member such as an anisotropic conductive film. Accordingly, the display panel 12 and the connecting member 14 may be electrically connected with each other.

In addition, the connecting member 14 may be connected to a plurality of circuit pads of the driver circuit board 15 through a conductive adhesive member such as an anisotropic conductive film. As a result, the connecting member 14 and the driver circuit board 15 may be electrically connected with each other.

The connecting member 14 may be a flexible printed circuit board or a chip-on film.

The driver circuit board 15 may be disposed under the panel bottom member 13 when the connecting member 14 is bent. The driver circuit board 15 may be a flexible printed circuit board (FPCB) that can be bent, a rigid printed circuit board (PCB) that is not easily bent, or a composite printed circuit board including both a rigid printed circuit board and a flexible printed circuit board.

The driver circuit board 15 may process the signal converted by a control circuit board (not shown) to transmit it to the display panel 12. The driver circuit board 15 may be electrically connected to the display panel 12 by the connecting member 14.

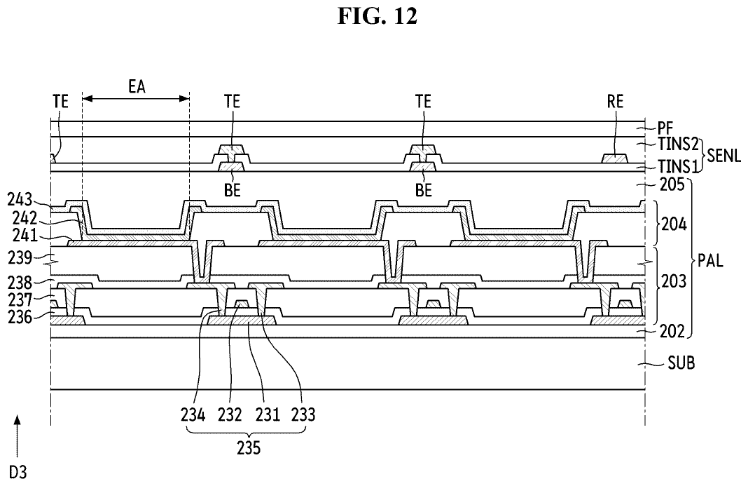

FIG. 12 is a cross-sectional view showing the display panel of FIG. 11.

Referring to FIG. 12, in an embodiment, the display unit PAL may include a buffer film 202, a thin-film transistor layer 203, a light-emitting element layer 204, and an encapsulation layer 205.

The buffer film 202 may be formed on the substrate SUB. The buffer film 202 may be formed on the substrate SUB to protect the thin-film transistors 235 and the light-emitting elements from moisture permeating through the substrate SUB that is susceptible to moisture permeation. The buffer film 202 may be formed of (or defined by) a plurality of inorganic layers stacked on one another alternately. In an embodiment, for example, the buffer film 202 may be made up of multiple layers in which one or more inorganic layer of a silicon oxide layer (SiOx), a silicon nitride layer (SiNx) and SiON are stacked on one another alternately. In another embodiment, the buffer film 202 may be omitted.

The thin-film transistor layer 203 is formed on the buffer film 202. The thin-film transistor layer 203 includes thin-film transistors 235, a gate insulator 236, an interlayer dielectric film 237, a protective film 238, and an organic film 239.

Each of the thin-film transistor 235 includes an active layer 231, a gate electrode 232, a source electrode 233, and a drain electrode 234. In an embodiment, as shown in FIG. 12, the thin-film transistors 235 may be implemented as top-gate transistors in which the gate electrode 232 is located above the active layer 231. It is, however, to be understood that the present disclosure is not limited thereto. In another embodiment, the thin-film transistors 235 may be implemented as bottom-gate transistors in which the gate electrode 232 is located below the active layer 231, or as double-gate transistors in which the gate electrodes 232 are disposed above and below the active layer 231.

The active layer 231 is formed on the buffer layer 202. The active layer 231 may include or be formed of a silicon-based semiconductor material or an oxide-based semiconductor material. In an embodiment, for example, the active layer 231 may be formed of polycrystalline silicon, amorphous silicon, or an oxide semiconductor. A light-blocking layer for blocking external light incident on the active layer 231 may be formed between the buffer layer 202 and the active layer 231.

The gate insulator 236 may be formed on the active layer 231. The gate insulator 236 may be formed of an inorganic layer, for example, a silicon oxide layer (SiOx), a silicon nitride layer (SiNx), or a multilayer thereof.

The gate electrodes 232 may be formed on the gate insulating layer 236. The gate electrodes 232 and the gate lines may be made up of (or defined by) a single layer or multiple layers of at least one selected from molybdenum (Mo), aluminum (Al), chromium (Cr), gold (Au), titanium (Ti), nickel (Ni), neodymium (Nd) and copper (Cu) or an alloy thereof.

The interlayer dielectric film 237 may be formed over the gate electrodes 232 and the gate lines. The interlayer dielectric film 237 may include or be formed of an inorganic layer, for example, a silicon oxide layer (SiOx), a silicon nitride layer (SiNx), or a multilayer thereof.

The source electrodes 233 and the drain electrodes 234 may be formed on the interlayer dielectric film 237. Each of the source electrodes 233 and the drain electrodes 234 may be connected to the active layer 231 through a contact hole defined through the gate insulating layer 236 and the interlayer dielectric layer 237. The source electrode 233 and the drain electrode 234 may be made up of (or defined by) a single layer or multiple layers of one of molybdenum (Mo), aluminum (Al), chromium (Cr), gold (Au), titanium (Ti), nickel (Ni), neodymium (Nd) and copper (Cu) or an alloy thereof.

The protective film 238 may be formed on the source electrode 233 and the drain electrode 234 to insulate the thin-film transistors 235. The protective film 238 may include or be formed of an inorganic layer, e.g., a silicon oxide layer (SiOx), a silicon nitride layer (SiNx), or a multilayer thereof.

The organic film 239 may be formed on the protective film 238 to provide a flat surface over the thin-film transistors 335 having difference levels. The organic film 239 may be implemented as an organic layer such as an acryl resin, an epoxy resin, a phenolic resin, a polyamide resin and a polyimide resin.

The light-emitting element layer 204 is formed on the thin-film transistor layer 203. The light-emitting element layer 204 includes the light-emitting elements and a bank.

The light-emitting elements and the bank are formed on the organic film 239. An organic light-emitting device including an anode electrode 241, emissive layers 242 and a cathode electrode 243 is employed as an example of the light-emitting elements.

The anode electrode 241 may be formed on the organic film 239. The anode electrode 241 may be connected to the source electrode 233 of the thin-film transistor 235 via a contact hole penetrating through the protective film 238 and the organic film 239.

The bank may be formed to cover the edge of the anode electrode 241 on the organic film 239 to define the emission areas EA of the pixels. In such an embodiment, the bank may define the emission areas EA of the pixels. In each of the pixels, the anode electrode 241, the emissive layer 242 and the cathode electrode 243 are sequentially stacked on one another so that holes from the anode electrode 241 and electrons from the cathode electrode 243 combine each other in the emissive layer 242 to emit light.

The emissive layers 242 are formed on the anode electrode 241 and the bank. The emissive layers 242 may be organic emissive layers. The emissive layers 242 may emit one of red light, green light, and blue light. Alternatively, the emissive layer 242 may be a white emissive layer that emits white light. In such an embodiment, the red emissive layer, the green emissive layer and the blue emissive layer may be stacked on one another or may be formed commonly across the pixels as a common layer. In such an embodiment, the display panel 200 may further include additional color filters for representing red, green and blue colors.

The emissive layer 242 may include a hole transporting layer, a light-emitting layer, and an electron transporting layer. In addition, the emissive layer 242 may be formed in a tandem structure of two or more stacks, in which case a charge generating layer may be formed between the stacks.

The cathode electrode 243 is formed on the emissive layer 242. The cathode electrode 243 may be formed to cover the emissive layer 242. The cathode electrode 243 may be a common layer formed across the pixels.

In an embodiment where the light-emitting element layer 204 is of a top-emission type in which light exits toward the upper side, the anode electrode 241 may be made of a metal material having a high reflectivity such as a stack structure of aluminum and titanium (Ti/Al/Ti), a stack structure of aluminum and ITO (ITO/Al/ITO), an APC alloy and a stack structure of APC alloy and ITO (ITO/APC/ITO). The APC alloy is an alloy of silver (Ag), palladium (Pd) and copper (Cu). The cathode electrode 243 may be formed of a transparent conductive material (TCP) such as ITO and IZO that can transmit light, or a semi-transmissive conductive material such as magnesium (Mg), silver (Ag) and an alloy of magnesium (Mg) and silver (Ag). In an embodiment where the cathode electrode 243 is formed of a translucent conductive material, the light extraction efficiency can be increased by using microcavities.

In an embodiment where the light-emitting element layer 204 is of a bottom-emission type in which light exits toward the lower side, the anode electrode 241 may include or be formed of a transparent conductive material (TCP) such as ITO and IZO that can transmit light, or a semi-transmissive conductive material such as magnesium (Mg), silver (Ag) and an alloy of magnesium (Mg) and silver (Ag). The cathode electrode 243 may be made of a metal material having a high reflectivity such as a stack structure of aluminum and titanium (Ti/Al/Ti), a stack structure of aluminum and ITO (ITO/Al/ITO), an APC alloy and a stack structure of APC alloy and ITO (ITO/APC/ITO). In an embodiment where the anode electrode 241 is formed of a semi-transmissive conductive material, the light extraction efficiency can be increased by using microcavities.

The encapsulation layer 205 is formed on the light-emitting element layer 204. The encapsulation layer 205 serves to prevent permeation of oxygen or moisture into the emissive layers 242 and the cathode electrode 243. In such an embodiment, the encapsulation layer 205 may include at least one inorganic film. The inorganic layer may include or be formed of silicon nitride, aluminum nitride, zirconium nitride, titanium nitride, hafnium nitride, tantalum nitride, silicon oxide, aluminum oxide, or titanium oxide. In an embodiment, the encapsulation layer 205 may further include at least one organic film. The organic film may have a sufficient thickness to effectively prevent particles from permeating into the encapsulation layer 205 and entering the emissive layer 242 and the cathode electrode 243. The organic layer may include at least one selected from epoxy, acrylate and urethane acrylate.

The sensor unit SENL may be formed on the encapsulation layer 205. When the sensor unit SENL is formed directly on the encapsulation layer 205, the thickness of the display device 10 can be reduced, compared with a display device in which a separate touch panel is attached on the encapsulation layer 205.

The sensor unit SENL may include sensor electrodes for sensing a user's touch by capacitive sensing, and touch lines for connecting the pads with the sensor electrodes. In an embodiment, for example, the sensor unit SENL can sense a user's touch by self-capacitance sensing or mutual capacitance sensing. In an embodiment, as shown in FIG. 12, the sensor unit SENL is made up of (or defined by) two layers including driving electrodes TE, sensing electrodes RE and bridges BE connecting between the driving electrodes TE for mutual capacitance sensing.

The bridges BE may be formed on the encapsulation layer 205. The bridges BE may include or be made up of, but is not limited to, a stack structure of aluminum and titanium (Ti/Al/Ti), a stack structure of aluminum and ITO (ITO/Al/ITO), an APC alloy and a stack structure of APC alloy and ITO (ITO/APC/ITO). In an embodiment, for example, the bridges BE may have a single layer of molybdenum (Mo), titanium (Ti), copper (Cu), aluminum (Al) or ITO.

A first sensing insulating film TINS1 is formed over the bridge electrodes BE. The first sensing insulating film TINS1 may be formed of an inorganic film, for example, a silicon nitride layer, a silicon oxynitride layer, a silicon oxide layer, a titanium oxide layer, or an aluminum oxide layer.

The driving electrodes TE and the sensing electrodes RE may be formed on the first sensing insulating film TINS1. The driving electrode TE and the sensing electrode RE may be formed as, but is not limited to, a stack structure of aluminum and titanium (Ti/Al/Ti), a stack structure of aluminum and ITO (ITO/Al/ITO), an APC alloy and a stack structure of APC alloy and ITO (ITO/APC/ITO). In an embodiment, for example, the driving electrodes TE and the sensing electrodes RE may have a single layer of molybdenum (Mo), titanium (Ti), copper (Cu), aluminum (Al) or ITO.

Contact holes may be formed in the first sensing insulating film TINS1 which penetrate the first sensing insulating film TINS1 to expose the bridges BE. The driving electrodes TE may be connected to the bridges BE through the contact holes.

A second sensing insulating film TINS2 is formed over the driving electrodes TE and the sensing electrodes RE. The second sensing insulating film TINS2 may provide a flat surface over the driving electrodes TE, the sensing electrodes RE and the bridges BE which have different heights. The second sensing insulating film TINS2 may include or be formed of an organic layer such as an acryl resin, an epoxy resin, a phenolic resin, a polyamide resin and a polyimide resin.

The bridges BE connecting between the adjacent driving electrodes TE may be disposed on the encapsulation layer 205, and the driving electrodes TE and the sensing electrodes RE may be disposed on the first sensing insulating film TINS1. Therefore, the driving electrodes TE and the sensing electrodes RE may be electrically separated from each other at their intersections, while the sensing electrodes RE may be electrically connected with one another in a direction, and the driving electrodes TE may be electrically connected with one another in another direction.

The polarizing film PF may be disposed on the second sensing insulating film TINS2 and can effectively prevent the deterioration of image visibility of the display panel 200 due to reflection of external light.

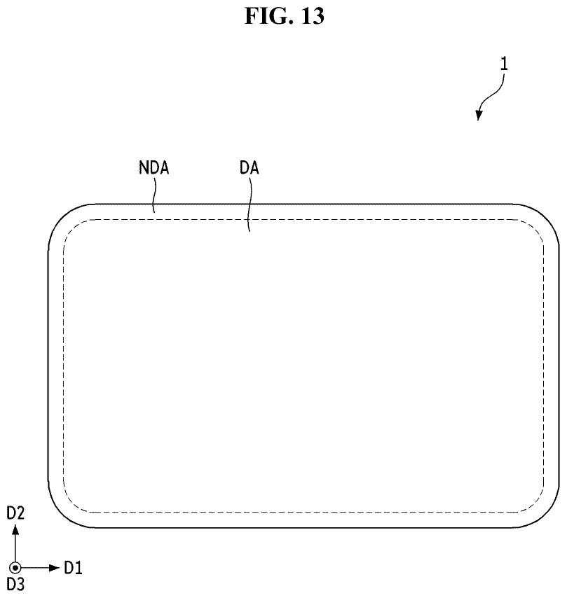

FIG. 13 is a plan view of an electronic device fabricated by a deposition apparatus according to an embodiment of the present disclosure.

Referring to FIG. 13, an electronic device 1 fabricated by the deposition apparatus 100 according to an embodiment of the present disclosure may include a display device 10 that provides a display screen. Examples of the electronic device 1 may include, but are not limited to, a mobile phone, a smart phone, a tablet personal computer (PC), a mobile communications terminal, an electronic organizer, an e-book, a personal digital assistant (PDA), a portable multimedia player (PMP), a navigation device, an ultra mobile PC (UMPC), a television set, a game machine, a wristwatch-type electronic device, a head-mounted display, a personal computer monitor, a laptop computer, a vehicle instrument cluster, a digital camera, a camcorder, an outdoor billboard, an electronic billboard, various medical apparatuses, various inspection devices, various home appliances including a display area such as a refrigerator and a laundry machine, Internet of things (IoT) devices, etc. Examples of the electronic device 1 may include, but are not limited to, a smartphone, a tablet PC, a laptop computer, etc.

The electronic device 1 may include a display area DA and a non-display area NDA. The shape of the display area DA may follow the shape of the electronic device 1 when viewed from the top. In an embodiment, for example, when the electronic device 1 has a rectangular shape when viewed from the top or in the third direction D3, the display area DA may also have a rectangular shape when viewed from the top.

The display area DA may include a plurality of pixels of the display device 10 to display images. The non-display area NDA may display no image because it does not include the pixels of the display device 10. The non-display area NDA may be disposed around the display area DA. The non-display area NDA may surround the display area DA, but the example embodiments of the present disclosure are not limited thereto. The display area DA may be partially surrounded by the non-display area NDA.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition apparatus comprising:
a deposition source including a plurality of deposition nozzles arranged in a direction to spray a deposition material;
a rail disposed along a direction in which the deposition nozzles are arranged above the deposition source; and
a moving module disposed on the rail, wherein the moving module moves along the rail,
wherein the moving module comprises:
a carrier on which a substrate is loaded;
a deposition mask supported by the carrier and disposed under the substrate;
a camera disposed on the carrier, wherein the camera captures an image of the deposition nozzles;
a laser irradiator disposed on the carrier, wherein the laser irradiator radiates a laser toward the deposition nozzles; and
a controller which analyzes the image captured by the camera and controls the laser irradiator.

2. The apparatus of claim 1, further comprising:
a chamber in which the deposition source, the rail and the moving module are accommodated, and
wherein the moving module further comprises: an acoustic sensor which detects sound inside the chamber, and
wherein the controller analyzes the sound detected by the acoustic sensor to control an operation of the rail.

3. The apparatus of claim 1, wherein the substrate is disposed under the carrier, and
wherein the moving module further comprises: a mask support extending downward from the carrier to support the deposition mask in a way such that the deposition mask is spaced apart from the carrier.

4. The apparatus of claim 1, wherein an opening is defined through the carrier in a thickness direction of the carrier, and
wherein the substrate and the deposition mask at least partially overlap the opening.

5. The apparatus of claim 1, wherein the camera and the laser irradiator are disposed at an end of the carrier in a direction in which the carrier moves.

6. The apparatus of claim 5, wherein the camera is disposed further to a front than the laser irradiator in the direction in which the carrier moves.

7. The apparatus of claim 1, wherein the controller compares the image of the deposition nozzles captured by the camera with an image of the deposition nozzles acquired in advance, and controls the laser irradiator to radiate laser to foreign substances at the deposition nozzles when it is determined that the foreign substances are accumulated at the deposition nozzles.

8. The apparatus of claim 2, wherein the controller compares sound inside the chamber detected by a sound sensor with sound inside the chamber acquired in advance, and, interrupts an operation of the rail when the sound inside the chamber detected by the sound sensor is different from the sound inside the chamber acquired in advance based on a comparison result.

9. The apparatus of claim 8, wherein the controller interrupts the operation of the rail when a decibel of the sound detected by the sound sensor is different from a decibel of the sound acquired in advance.

10. The apparatus of claim 8, wherein the controller interrupts the operation of the rail when a sound wave of the sound detected by the sound sensor is different from a sound wave of the sound acquired in advance.

11. A deposition method of a display device, the method comprising:
loading a substrate, on which a deposition material is to be deposited, on a carrier of a moving module;
moving the moving module along a rail disposed above deposition nozzles in a direction in which the deposition nozzles are arranged;
capturing an image of the deposition nozzles by a camera of the moving module; and
controlling, by a controller of the moving module, a laser irradiator of the moving module by analyzing the image captured by the camera.

12. The method of claim 11, wherein the controlling, by the controller, the laser irradiator by analyzing the image captured by the camera comprises:
comparing, by the controller, the image of the deposition nozzle captured by the camera with an image of the deposition nozzle acquired in advance; and
controlling, by the controller, the laser irradiator to radiate a laser based on a comparison result.

13. The method of claim 12, wherein the controlling, by the controller, the laser irradiator to radiate the laser based on the comparison result comprises:
controlling, by the controller, the laser irradiator to radiate the laser to foreign substances at the deposition nozzle when there is a foreign substance in the image captured by the camera which was not in the image acquired in advance.

14. The method of claim 11, further comprising:
detecting, by a sound sensor of the moving module, sound inside a chamber, in which the deposition nozzles, the rail and the moving module are accommodated; and
controlling, by the controller of the moving module, an operation of the rail by analyzing the sound detected by the sound sensor.

15. The method of claim 14, wherein the controlling, by the controller, the operation of the rail by analyzing the sound detected by the sound sensor comprises:
comparing, by the controller, the sound inside the chamber detected by the sound sensor with sound inside the chamber acquired in advance; and
interrupting, by the controller, the operation of the rail based on a comparison result.

16. The method of claim 15, wherein the interrupting, by the controller, the operation of the rail based on the results of the comparing comprises: interrupting, by the controller, the operation of the rail when the sound detected by the sound sensor is different from the sound acquired in advance.

17. The method of claim 15, wherein the interrupting, by the controller, the operation of the rail based on the comparison result comprises:
interrupting, by the controller, the operation of the rail when a decibel of the sound detected by the sound sensor is different from a decibel of the sound acquired in advance.

18. The method of claim 15, wherein the interrupting, by the controller, the operation of the rail based on the comparison result comprises:
interrupting, by the controller, the operation of the rail when a sound wave of the sound detected by the sound sensor is different from a sound wave of the sound acquired in advance.

19. An electronic device comprising a display device fabricated by a deposition apparatus, wherein the deposition apparatus comprises:
a deposition source having a plurality of deposition nozzles arranged in a direction to spray a deposition material;
a rail disposed along a direction in which the deposition nozzles are arranged above the deposition source; and
a moving module disposed on the rail, wherein the moving module moves along the rail,
wherein the moving module comprises:
a carrier on which a substrate is loaded;
a deposition mask supported by the carrier and disposed under the substrate;
a camera disposed on the carrier, wherein the camera captures an image of the deposition nozzles;
a laser irradiator disposed on the carrier, wherein the laser irradiator radiates a laser toward the deposition nozzles; and
a controller which analyzes the image captured by the camera and controls the laser irradiator.

20. The electronic device of claim 19, wherein the deposition apparatus further comprises: a chamber in which the deposition source, the rail and the moving module are accommodated,
wherein the moving module further comprises: an acoustic sensor which detects sound inside the chamber, and
wherein the controller analyzes the sound detected by the acoustic sensor to control an operation of the rail.
